(19) United States
(12) Patent Application Publication
(10) Pub. No.: US 2013/0061458 A1
(43) Pub. Date: Mar. 14, 2013

(54) SUPERCONDUCTING JOINT METHOD FOR FIRST GENERATION HIGH-TEMPERATURE SUPERCONDUCTING TAPE

(71) Applicants: Haigun Lee, Dongdaemun-gu (KR); Jung-Bin Song, Gangnam-gu (KR); Jong-Hoon Lee, Gwangsan-gu (KR)

(72) Inventors: Haigun Lee, Dongdaemun-gu (KR); Jung-Bin Song, Gangnam-gu (KR); Jong-Hoon Lee, Gwangsan-gu (KR)

(73) Assignee: KOREA UNIVERSITY RESEARCH AND BUSINESS FOUNDATION, Seoul (KR)

(21) Appl. No.: 13/635,754

(22) PCT Filed: Mar. 10, 2011
(86) PCT No.: PCT/KR11/01655

§ 371 Date: Nov. 21, 2012

(30) Foreign Application Priority Data
Mar. 19, 2010 (KR) 10-2010-0024959

(51) Int. Cl. H01L 39/24

(52) U.S. Cl. 29/599

(57) ABSTRACT

Provided is a superconducting joining method of first generation superconducting wire, including: removing normal conductor parts from joining portions of first generation superconducting wires to be joined to each other, thereby exposing superconducting filaments; after inserting a superconductor powder into the joining portions, bring the superconducting filaments of the first generation superconducting wires to be joined to each other into contact with each other, and applying a pressure thereon; and causing the first generation superconducting wires that are brought into contact with each other to be subjected to melting diffusion and joined to each other, thereby minimizing a reduction in critical current and joining resistance.

### TECHNICAL FIELD

This disclosure relates to a superconducting joining method of first generation high-temperature superconducting wires, and more particularly, a superconducting joining method of first generation high-temperature superconducting wires capable of enabling a closed circuit to be driven in a persistent current mode without any loss by removing the occurrence of joining resistance due to superconducting joining.

### BACKGROUND ART

The basic manufacturing process of a Bi 2223 superconducting wire is classified into powder manufacturing, filling of an Ag pipe with the powder, drawing or rolling of a wire, and sintering.

The first generation high-temperature superconducting wire including the Bi 2223 superconducting wire is made by drawing superconductors in filament forms in a silver sheath (Ag sheath) and performing a heat treatment thereon using the powder-in-tube method. Unlike a second generation high-temperature superconducting wire, the first generation high-temperature superconducting wire has good ductility and is easily formed into wires or tapes, thereby being used in various superconducting application devices.

When a sufficiently long superconducting wire required during coil winding is manufactured, joining of superconducting wires is generally indispensable to superconducting magnets and superconducting application devices which essentially require a persistent current mode, such as Nuclear Magnetic Resonance (NMR), Magnetic Resonance Imaging (MRI), Superconducting Magnet Energy Storage (SMES), and MAGnetic LEVitation (MAGLEV) systems. Here, when a driving current is applied to the coil, driving has to be achieved without any loss as if all the windings were made using a single wire.

At cryogenic temperature in the vicinity of the evaporation temperature (77 K) of liquid nitrogen at which a superconducting state is maintained, most of current flow is made through superconductor layers, and thus a state in which there is no current loss and the resistance is zero is maintained. Therefore, in many superconducting devices or systems using superconductors, joining between superconductors is necessary, and in this case, current and resistance characteristics at the superconducting joining part become the most important factors for driving in the persistent current mode.

Success or fail of the joining between superconducting wires may be determined by whether or not the critical current is reduced and the resistance is minimized at the joining part.

Joining of superconducting wires is used as a method to overcome a difficulty in manufacturing a wire long enough to be applied to various systems. The joining of superconducting wires includes normal-conducting joining in which a normal-conducting material such as a solder is used between superconducting materials as a medium and superconducting joining in which superconductors are directly joined to each other. In a case where current flows through the superconducting wires using the normal-conducting joining, the current inevitably flows through the normal-conducting part, and thus joining resistance occurs. Therefore, in application to the superconducting system, there is a possibility that a quench where the superconductors are suddenly changed to normal conductors by Joule heating due to the joining resistance may occur, and driving in the persistent current mode is impossible due to a reduction in current. Therefore, a method of minimizing joining resistance when superconducting wires are joined is needed.

### DISCLOSURE

### Technical Problem

This disclosure is directed to providing a superconducting joining method of first generation high-temperature superconducting wires capable of minimizing joining resistance due to joining.

### Technical Solution

In one general aspect, there is provided a superconducting joining method of first generation superconducting wires, including: removing normal conductor parts from joining portions of first generation superconducting wires to be joined to each other, thereby exposing superconducting filaments; after inserting a superconductor powder into the joining portions, bring the superconducting filaments of the first generation superconducting wires to be joined to each other into contact with each other, and applying a pressure thereon; and causing the first generation superconducting wires that are brought into contact with each other to be subjected to melting diffusion and joined to each other.

According to an embodiment, the causing of the first generation superconducting wires that are brought into contact with each other to be subjected to melting diffusion and joined to each other is causing the first generation superconducting wires that are brought into contact with each other to be subjected to melting diffusion and joined to each other after performing heating to a melting point of at least one of the superconductor powder and the superconducting filaments under the partial pressure of oxygen at which the melting points of the superconductor powder and the superconducting filaments are maintained lower than a melting point of a normal conductor.

In addition, the causing of the first generation superconducting wires that are brought into contact with each other to be subjected to melting diffusion and joined to each other may further include supplying oxygen to the first generation superconducting wires that are brought into contact with each other.

In addition, the first generation superconducting wire may be one of BSCCO 2233 and BSCCO 2212, and the normal conductor may be a silver matrix.

In addition, a melting point of the inserted superconductor powder may have a thermodynamically lower activation energy and be lower than a melting point of the superconducting filaments.

### Advantageous Effects

According to the present disclosure, the normal conductor part of a state where the superconducting wires are joined to each other is removed by an etching method, the powder of the first generation high-temperature superconductor is inserted between the superconducting surfaces to be joined to each other as a filler, and then the superconducting wires are joined to each other through melting diffusion of the superconducting powder, thereby minimizing the joining resistance due to joining. In addition, according to the present disclosure, since joining resistance rarely occurs compared to normal-conducting joining, a difficulty in manufacturing a sufficiently long wire is solved and thus applications to various systems may be achieved. Furthermore, according to the present disclosure, superconducting joining is simply achieved by the heat treatment regardless of the kind of the base material of the superconducting wire or a stabilizer layer as long as a normal-conducting layer is removed, and thus the present disclosure is conveniently used to manufacture superconducting systems in practice.

### DESCRIPTION OF DRAWINGS

The above and other aspects, features and advantages of the disclosed exemplary embodiments will be more apparent from the following detailed description taken in conjunction with the accompanying drawings in which:

FIG. 1 schematically illustrates the basic structure of a first generation high-temperature superconducting wire;

FIG. 2 illustrates an example of a method of directly joining first generation high-temperature superconducting wires using high-temperature superconductor powder according to an embodiment of the present disclosure;

FIG. 3 illustrates an apparatus for applying a uniform pressure to the joining surfaces between the first generation high-temperature superconducting wires and a wire according to an embodiment of the present disclosure;

FIG. 4 illustrates a process of melting diffusion of the superconducting powder at the joining surfaces during superconducting joining between the first generation high-temperature superconducting wires; and

FIG. 5 is a flowchart of a superconducting joining method of first generation high-temperature superconducting wires according to an embodiment of the present disclosure.

### BEST MODE

A superconducting joining method of first generation superconducting wires according to an embodiment of the present disclosure, includes: removing normal conductor parts from joining portions of first generation superconducting wires to be joined to each other, thereby exposing superconducting filaments; after inserting a superconductor powder into the joining portions, bring the superconducting filaments of the first generation superconducting wires to be joined to each other into contact with each other, and applying a pressure thereon; and causing the first generation superconducting wires that are brought into contact with each other to be subjected to melting diffusion and joined to each other.

### MODE FOR INVENTION

Hereinafter, the present disclosure will be described in more detail with reference to the exemplary embodiments. However, the embodiments are for describing the present disclosure more specifically, and it will be understood by those skilled in the art that the scope of the present disclosure is not limited by the embodiments. The configuration of the present disclosure for clarifying the solution of the problem to be solved by the present disclosure will be described in detail with reference to the accompanying drawings on the basis of the exemplary embodiments of the present disclosure. When elements in the drawings are denoted by reference numerals, like elements are denoted by like reference numerals although the elements are in different drawings, and it is noted in advance that elements in different drawings are quoted in a case where description of corresponding drawings is needed. In addition, in a case where it is determined that detailed description of well-known features and configurations according to the present disclosure and all other matters unnecessarily obscure the gist of the present disclosure, the detailed description will be omitted.

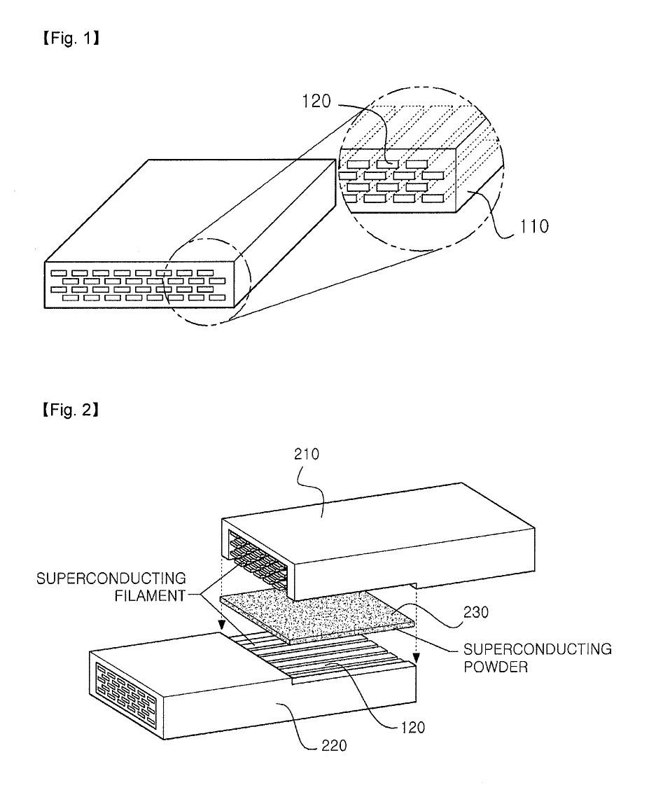

FIG. 1 schematically illustrates the basic structure of a first generation high-temperature superconducting wire.

Referring to FIG. 1, the first generation high-temperature superconducting wire includes a normal conductor 110 and superconducting filaments 120.

The normal conductor 110 is made of silver (Ag) or a silver alloy and includes the superconducting filaments 120. The normal conductor 110 may be a silver matrix.

The superconducting filaments 120 have superconducting crystals aligned only with a single axis and may have BSCCO 2223 or BSCCO 2212 as the material. A plurality of the superconducting filaments 120 are arranged in the normal conductor 110 at constant intervals.

FIG. 2 illustrates an example of a method of directly joining first generation high-temperature superconducting wires using high-temperature superconductor powder according to an embodiment of the present disclosure.

Referring to FIG. 2, a state in which, when a first generation high-temperature superconducting wire 210 and another first generation high-temperature superconducting wire 220 are to be joined, an uppermost normal conductor 110 part of each of the first generation high-temperature superconducting wires is removed is illustrated.

When the normal conductor part of the first generation high-temperature superconducting wire 210 is removed, the superconducting filaments 120 are exposed, and similarly, the superconducting filaments of the first generation high-temperature superconducting wire 220 are also exposed.

Normal-conducting joining is a method of joining two wires using indium (In), Pb/Sn, wood metal, and silver plate as insertion materials, while superconducting joining is a method of causing superconductors to come into direct contact with each other.

According to an embodiment of the present disclosure, superconducting powder 230 is inserted into the joining parts of the first generation high-temperature superconducting wire 210 and the first generation high-temperature superconducting wire 220, and the two first generation high-temperature superconducting wires are joined in a lap joint method through a melding diffusion method.

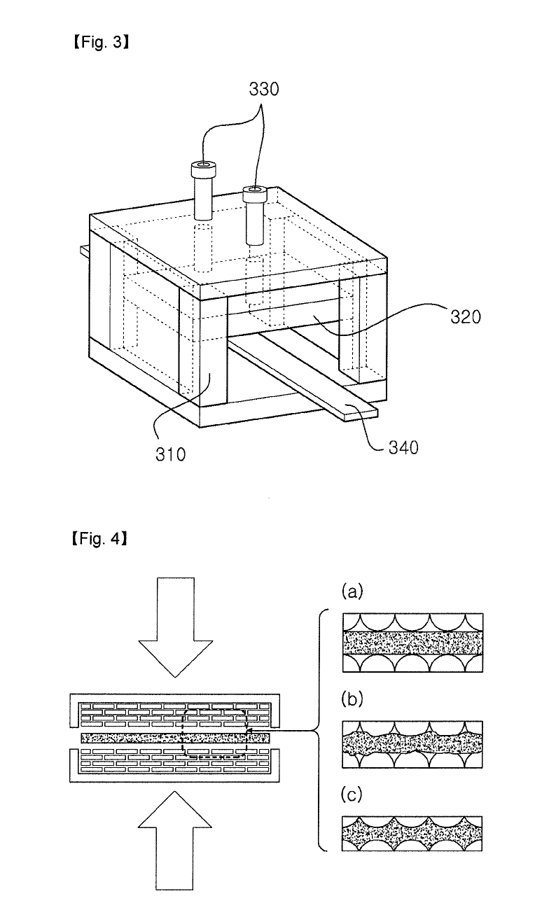

FIG. 3 illustrates an apparatus for applying a uniform pressure to the joining surfaces between the first generation high-temperature superconducting wires and a wire according to an embodiment of the present disclosure.

During melting diffusion of the superconducting powder inserted into the joining surfaces of the first generation high-temperature superconducting wires, in order to cause the superconducting powder to uniformly permeate the grain boundaries of the superconductors and empty spaces and induce strong bonding, an apparatus capable of uniformly applying a pressure to the joining surfaces is needed.

Referring to FIG. 3, the apparatus for applying a uniform pressure to the joining surfaces between the first generation high-temperature superconducting wires according to an embodiment of the present disclosure includes a wire holder 310, a pressure unit 320, and a tightening unit 330.

When superconducting wires 340 in a state in which the superconducting wires are joined are tightened while controlling the torque of the tightening unit 330 in order to apply an appropriate pressure to the superconducting joining surfaces, the pressure at the superconducting surfaces may be easily controlled. In addition, the tightening unit 330 may be a screw.

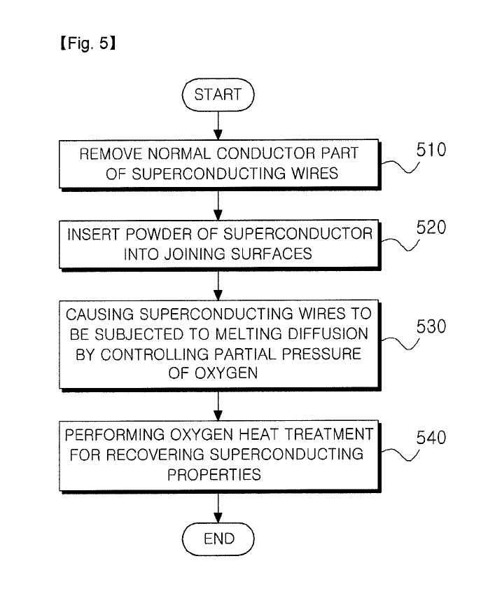

FIG. 4 illustrates a process of melting diffusion of the superconducting powder at the joining surfaces during superconducting joining between the first generation high-temperature superconducting wires.

FIG. 4(a) illustrates a state where the superconducting powder is inserted between the superconducting wires before melting diffusion.

FIG. 4(b) illustrates a state where melting diffusion of the superconducting powder proceeds. The superconducting powder is melted at a temperature lower than that of the superconducting filaments, and the superconducting powder melted in advance permeates the grain boundaries of the superconductors or empty spaces around due to the pressure of the pressure unit 320 and the capillary phenomenon, thereby strengthening bonding between the superconductors.

FIG. 4(c) illustrates a state where an empty space that occurs due to the joining of the superconducting wires is filled with the superconducting powder as a result of the melting diffusion of the superconducting powder.

FIG. 5 is a flowchart of a superconducting joining method of first generation high-temperature superconducting wires according to an embodiment of the present disclosure.

In operation 510, the normal conductor parts of the superconducting wires are removed.

The normal conductor parts of the joining sites of the superconducting wires are removed by a chemical etching method. Here, the normal conductor parts removed from the superconducting wires are parts corresponding to the joining portions, and by immersing the joining portions into an acid solution, the normal conductor parts may be chemically removed.

In consideration of a time for which the superconducting wires are immersed into the acid solution, the degree of acidification of the acid solution, and the like, the superconducting wires may be bonded after removing all the normal conductor 110 surrounding the superconducting filaments 120 at the joining portions of the superconducting wires and remaining only the superconducting filaments 120, or the normal conductor 110 only at the outermost part of the superconducting wires may be removed and the exposed superconducting filaments 120 may be brought into contact to be bonded.

In operation 520, the superconductor powder is inserted into the joining surfaces.

After removing the normal conductor parts of the superconductors, the powder of the first generation high-temperature superconductor is inserted between superconducting surfaces to be joined to each other as a filler. Here, the form of the joining may be various forms including a lap joint and a butt joint.

In the case where the normal conductor 110 only at the outermost part of the superconducting wires is removed and the exposed superconducting filaments 120 may be brought into contact to be bonded, the same kind of superconductor powder as that of the superconducting wire may be inserted into the joining portions. However, the same kind of superconductor powder as that of the superconducting wires to be joined is not necessarily used, and other kinds of superconductor powder may also be used.

In the case where the superconductors are used for joining in the form of powder, the particle sizes are small and thus the activation energy thereof is thermodynamically low. Therefore, melting diffusion is possible with low energy and thus superconducting joining is facilitated, and the melted powder permeates the grain boundaries of the normal conductor 110 or the superconducting filaments 120 through the capillary phenomenon, thereby further strengthening the superconducting joining.

In operation 530, the superconducting wires are subjected to melting diffusion by controlling the partial pressure of oxygen.

The melting point (960° C.) of silver during melting diffusion is higher than that of the first generation high-temperature superconductor (BSCCO 2223). Therefore, when a heat treatment is performed in a temperature range of less than or equal to the melting point of silver, joining between the superconductors is possible without melting of silver.

That is, when the heat treatment is performed in the temperature range in which only the first generation high-temperature superconductors are melted without melting of silver while applying a pressure to the joining sites, joining between the superconducting layers is achieved through the melting diffusion of the superconducting powder. Here, a uniform pressure is applied so that the high-temperature superconducting powder is uniformly distributed without generating voids on the joining surfaces. The melted high-temperature superconducting powder permeates the grain boundaries of the superconductors due to the capillary phenomenon, thereby strengthening the bonding between the superconductors.

Particularly, the superconductor powder is inserted into the joining portions. Since the superconductor powder has thermodynamically low activation energy and is melted faster than the superconductor filaments 120, superconducting joining may be achieved within a short time.

In a case where the superconducting powder is of the same kind as that of the superconductor filaments, the superconducting powder is melted faster than the superconductor filaments even through they have the same melting point, and thus superconducting joining may be achieved more rapidly. In addition, in a case where the superconducting powder is of a different kind from that of the superconductor filaments and the melting point of the superconducting powder is lower than that of the superconductor filaments, the superconducting powder may undergo melting diffusion and achieve superconducting joining without affecting the superconductor filaments.

In addition, when the partial pressure of oxygen is reduced, the melting point of the high-temperature superconductor is reduced, and thus joining is possible even at a temperature that is significantly different from the melting point of silver. In this case, the superconducting joining process is more easily performed.

A method of achieving melting joining more easily by reducing the partial pressure of oxygen and further reducing the melting point of the first generation high-temperature superconductor will be described in more detail.

First, superconducting wires are brought into contact with each other and are fixed by inserting a superconducting powder into the joining surfaces. Thereafter, the fixed part is put into a furnace and is heated to the melting point of the superconductor powder or the melting point of superconductor filaments in a state where the partial pressure of oxygen is reduced to be lower than the normal pressure, and then the superconductor filaments that are brought into contact with each other are subjected to melting diffusion or the superconducting powder is subjected to melting diffusion, thereby achieving superconducting joining.

Here, in order to induce bonding by melting diffusion using a change in the melting point of the superconductor filaments or the superconducting powder due to the partial pressure of oxygen, temperature may be controlled. That is, the reason that the heating temperature for achieving melting diffusion is controlled is to prevent the occurrence of deformation or contamination due to a high temperature at a part excluding the superconductor filaments at the heating temperature.

In operation 540, the joining surfaces of the superconducting wires are subjected to an oxygen heat treatment in order to recover superconducting properties. The oxygen heat treatment includes a process of oxidization in an oxygen atmosphere, and the oxygen atmosphere is achieved by continuously circulating and supplying oxygen into the furnace in which oxygenation annealing is performed.

A time to perform oxygenation annealing has to be controlled because in a case where oxygenation annealing is performed in an oxygen atmosphere for a long period time over a predetermined time, the oxygen content is increased, and when oxygenation annealing is not performed for a sufficient time, the oxygen content is insufficient and superconducting properties are lost.

As described above, according to an embodiment of the present disclosure, the superconducting filaments are directly connected to each other without an intermediate medium and most of the flow of current flowing through the superconducting wires is connected to another superconducting wire through the superconductor having a resistance of 0, and thus resistance that occurs due to joining may be minimized.

In addition, according to the present disclosure, through superconducting joining in which the superconductor layers are directly connected after removing the normal conductors from the superconducting wires, a difficulty in manufacturing a sufficiently long superconducting wire is solved and operation in a persistent current mode is achieved. Therefore, the present disclosure may be applied to various superconducting systems in practice.

While the present disclosure have been described with reference to particular details such as specific elements, the embodiments, and the drawings as described above, this is provided only to help the overall understanding of the present disclosure and the present disclosure is not limited to the embodiments. It will be understood by those skilled in the art to which the present disclosure belongs that various modifications and changes may be made from the description. Therefore, the spirit of the present disclosure is not determined by being limited to the above-described embodiments, but the claims described later and all of those that are equivalent to the claims and equivalent modifications thereof belong to the spirit and scope of the present disclosure.

1. A superconducting joining method of first generation superconducting wires, comprising:
removing normal conductor parts from joining portions of first generation superconducting wires to be joined to each other, thereby exposing superconducting filaments;
after inserting a superconductor powder into the joining portions, bring the superconducting filaments of the first generation superconducting wires to be joined to each other into contact with each other, and applying a pressure thereon; and
causing the first generation superconducting wires that are brought into contact with each other to be subjected to melting diffusion and joined to each other.

2. The superconducting joining method of first generation superconducting wires according to claim 1,
wherein said causing of the first generation superconducting wires that are brought into contact with each other to be subjected to melting diffusion and joined to each other is causing the first generation superconducting wires that are brought into contact with each other to be subjected to melting diffusion and joined to each other after performing heating to a melting point of at least one of the superconductor powder and the superconducting filaments under the partial pressure of oxygen at which the melting points of the superconductor powder and the superconducting filaments are maintained lower than a melting point of a normal conductor of each of the first generation superconducting wires.

3. The superconducting joining method of first generation superconducting wires according to claim 2, further comprising supplying oxygen to the first generation superconducting wires that are brought into contact with each other.

4. The superconducting joining method of first generation superconducting wires according to claim 1,
wherein the first generation superconducting wire is one of BSCCO 2233 and BSCCO 2212.

5. The superconducting joining method of first generation superconducting wires according to claim 1,
wherein the normal conductor is a silver matrix.

6. The superconducting joining method of first generation superconducting wires according to claim 1,
wherein the removing of the normal conductor parts is performed by a chemical etching method.

7. The superconducting joining method of first generation superconducting wires according to claim 1,
wherein a melting point of the inserted superconductor powder is lower than a melting point of the superconducting filaments.
